(19) United States
(12) Patent Application Publication
(10) Pub. No.: US 2019/0080763 A1
(43) Pub. Date: Mar. 14, 2019

(54) SEMICONDUCTOR MEMORY DEVICE AND MEMORY SYSTEM

(71) Applicant: TOSHIBA MEMORY CORPORATION, Tokyo (JP)

(72) Inventors: Tomoko KAJIYAMA, Kamakura Kanagawa (JP); Akio SUGAHARA, Yokohama Kanagawa (JP); Yoshikazu HARADA, Kawasaki Kanagawa (JP); Daisuke ARIZONO, Yokohama Kanagawa (JP)

(21) Appl. No.: 15/982,205

(22) Filed: May 17, 2018

(30) Foreign Application Priority Data
Sep. 11, 2017 (JP) 2017-174033

(51) Int. Cl. G11C 16/04; G11C 16/10; H01L 27/11551; H01L 27/11578

(52) U.S. Cl. CPC G11C 16/04; G11C 16/10; G11C 2216/14; H01L 27/11578; H01L 27/11551

(57) ABSTRACT

A semiconductor memory device includes first and second planes, first and second latch circuits for the first plane of memory cells, wherein data stored in the first latch circuit is transferred to the first plane of memory cells via the second latch circuit, third and fourth latch circuits for the second plane of memory cells, wherein data stored in the third latch circuit is transferred to the second plane of memory cells via the fourth latch circuit, and a control circuit configured to perform a sequence of operations in response to commands, the sequence of operations including a first operation to transfer first data associated with the commands from the first latch circuit to the second latch circuit and, concurrently with the first operation, a second operation to transfer second data associated with the commands into the third latch circuit.

### CROSS-REFERENCE TO RELATED APPLICATION

This application is based upon and claims the benefit of priority from Japanese Patent Application No. 2017-174033, filed Sep. 11, 2017, the entire contents of which are incorporated herein by reference.

### FIELD

Embodiments described herein relate generally to a semiconductor memory device and a memory system.

### BACKGROUND

NAND flash memory is known as a type of semiconductor memory device. Furthermore, NAND flash memory that includes a plurality of memory cells that are stacked three-dimensionally on top of each other is known.

### DESCRIPTION OF THE DRAWINGS

FIG. 1 is a block diagram of a memory system according to a first embodiment.

FIG. 2 is a block diagram of a NAND flash memory that is illustrated in FIG. 1.

FIG. 3 is a block diagram of a plane that is provided in a memory cell array.

FIG. 4 is a circuit diagram of a block that is provided in the plane.

FIG. 5 is a cross-sectional diagram of one region of the block.

FIG. 6 is a schematic diagram of an example of a distribution of threshold voltages of a memory cell transistor.

FIG. 7 is a block diagram of a sense amplifier unit and a data register that are illustrated in FIG. 2.

FIG. 8 is a flowchart for describing a write operation.

FIG. 9 is a command sequence for describing a data input operation according to the first embodiment.

FIG. 10 is a schematic diagram for describing a flow of data during the data input operation that is illustrated in FIG. 9.

FIG. 11 illustrates states various status signals during the data input operation according to the first embodiment.

FIG. 12 is a command sequence for describing a data input operation according to a second embodiment.

FIG. 13 is a schematic diagram for describing a flow of data in the data input operation that is illustrated in FIG. 12.

FIG. 14 is a command sequence for describing a data input operation according to a modification example.

FIG. 15 is a schematic diagram for describing a flow of data in the data input operation that is illustrated in FIG. 14.

FIG. 16 is a command sequence for describing a data input operation according to a third embodiment.

### DETAILED DESCRIPTION

Embodiments provide a semiconductor memory device and a memory system that are capable of shortening the time for a write operation.

In general, according to one embodiment, a semiconductor memory device includes first and second planes, first and second latch circuits for the first plane of memory cells, wherein data stored in the first latch circuit is transferred to the first plane of memory cells via the second latch circuit, third and fourth latch circuits for the second plane of memory cells, wherein data stored in the third latch circuit is transferred to the second plane of memory cells via the fourth latch circuit, and a control circuit configured to perform a sequence of operations in response to commands, the sequence of operations including a first operation to transfer first data associated with the commands from the first latch circuit to the second latch circuit and, concurrently with the first operation, a second operation to transfer second data associated with the commands into the third latch circuit.

Embodiments will be described below with reference to the drawings. Embodiments described below provide devices and methods for embodying technological ideas disclosed herein, and the technological ideas are not limited to particular shapes, structures, and arrangements, and the like of the examples given herein. Each functional block can be implemented in hardware or software, or as a combination of both. Functional blocks are not limited to those given in the following examples. For example, one or several functions may be implemented in a functional block other than the particular functional block described herein. Moreover, the functional block that is described herein may be divided into functional sub-blocks. It is noted that in the following description, elements that have the same function and configuration are given the same reference numeral, and repeated descriptions are provided where necessary.

### 1. First Embodiment

### 1-1. Configuration of a Memory System

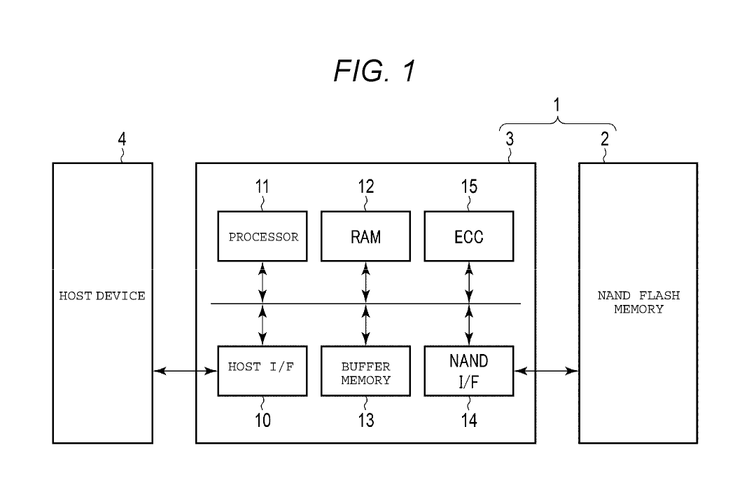

FIG. 1 is a block diagram of a memory system 1 according to a first embodiment. The memory system 1 includes a NAND flash memory 2 and a memory controller 3.

In the configuration of the memory system 1 illustrated in FIG. 1, a plurality of chips of the memory system 1 are mounted on a mother board that is equipped with a host device, and a system large-scale integrated circuit (LSI) or a system on chip (SoC) that can implement the memory system 1 in one module. As examples of the memory system 1, a memory card, such as a SD™ card, a solid state drive (SSD), an embedded multimedia card (eMMC), and the like are given.

NAND flash memory 2 includes a plurality of memory cells. Data is stored in the memory cells in a nonvolatile manner. The details of the NAND flash memory 2 will be described below.

For example, in response to a command from a host device 4, a memory controller 3 issues commands to perform operation, such as writing to, reading from, and erasing from the NAND flash memory 2. Furthermore, the memory controller 3 manages a memory space of the NAND flash memory 2. The memory controller 3 includes a host interface circuit (host I/F) 10, a processor 11, a random access memory (RAM) 12, a buffer memory 13, a NAND interface circuit (NAND I/F) 14, an error checking and correcting (ECC) circuit 15, and the like.

The host interface circuit 10 is connected to the host device 4 via a host bus, and performs processing for an interface to the host device 4. Furthermore, the host interface circuit 10 performs transmission and reception of a command, an address, and data to and from the host device 4.

The processor 11, for example, is a central processing unit (CPU). The processor 11 controls operation of the entire memory controller 3. For example, in the case of receiving a write command from the host device 4, the processor 11 issues a write command that is based on a NAND interface, to the NAND flash memory 2, as a response. This is also true for reading and erasing. Furthermore, the processor 11 performs various processing operations for managing the NAND flash memory 2, such as wear leveling.

The RAM 12 is used as a working area for the processor 11. Firmware is loaded into the RAM 12 from the NAND flash memory 2, and various tables and the likes that are created by the processor 11 are stored in the RAM 12. The RAM 12, for example, is a DRAM. Data that is transmitted from the host device 4 is temporarily retained in the buffer memory 13. Data that is transmitted from the NAND flash memory 2 is temporarily retained in the buffer memory 13 as well.

When writing data, the ECC circuit 15 generates an error correction code for write data, and sends the write data and the error correction code added thereto, to the NAND interface circuit 14. Furthermore, when reading data, using the error correction code that is included in read data, the ECC circuit 15 performs error detection and/or error correction on the read data. The ECC circuit 15 may be provided within the NAND interface circuit 14.

The NAND interface circuit 14 is connected to the NAND flash memory 2 via the NAND bus, and performs processing for an interface to the NAND flash memory 2. Furthermore, the NAND interface circuit 14 performs transmission and reception of a command, an address, and data to and from the NAND flash memory 2.

### 1-1-1. Configuration of the NAND Flash Memory 2

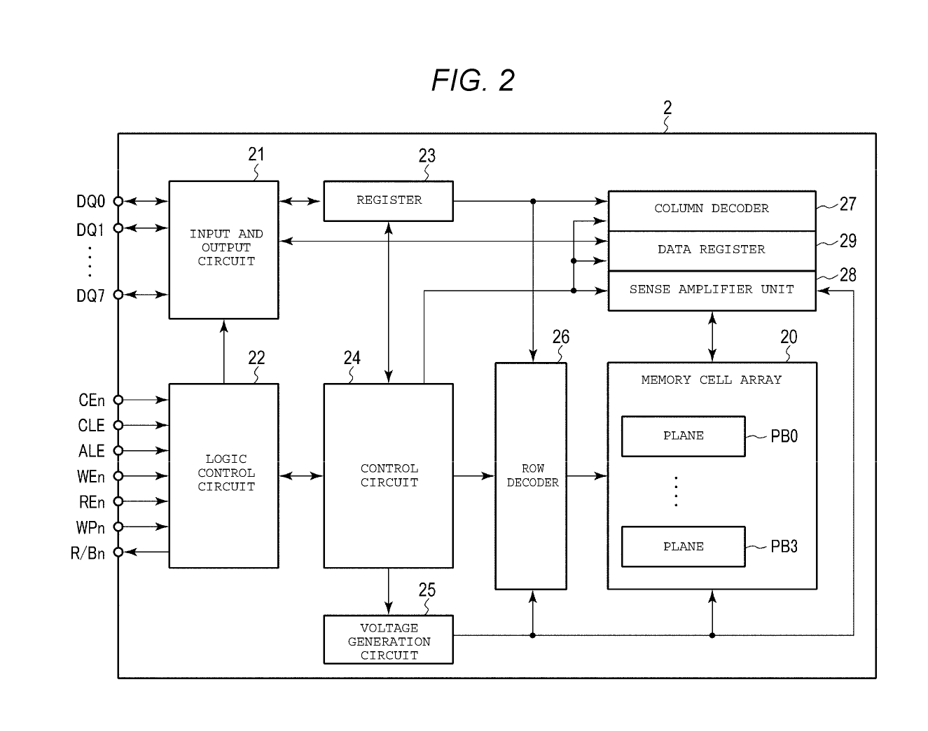

FIG. 2 is a block diagram of the NAND flash memory 2 that is illustrated in FIG. 1.

The NAND flash memory 2 includes a memory cell array 20, an input and output circuit 21, a logic control circuit 22, a register 23, a control circuit 24, a voltage generation circuit 25, a row decoder 26, a column decoder 27, a sense amplifier unit 28, and a data register 29.

The memory cell array 20 includes a plurality of planes PB. In FIG. 2, four planes, planes PB0 to PB3, are illustrated as one example, but the number of planes PB is not limited thereto. Each plane PB can perform a write operation, a read operation, and an erasing operation. Furthermore, a plurality of planes PB can perform operations in parallel. The plane PB includes a plurality of blocks. Each of the plurality of blocks includes a plurality of memory cell transistors. The memory cell transistor is configured in one example as EEPROM® cells that are electrically rewritable. In order to control a voltage that is applied to the memory cell transistor, a plurality of bit lines, a plurality of word lines, and source lines are arranged in the memory cell array 20. The details of the plane PB will be described below.

The input and output circuit 21 and the logic control circuit 22 are connected to the memory controller 3 via the NAND bus. The input and output circuit 21 transmits and receives signals DQ (for example, DQ0 to DQ7) to and from the memory controller 3 via the NAND bus.

The logic control circuit 22 receives external control signals (for example, a chip enable signal CEn, a command latch enable signal CLE, an address latch enable signal ALE, write enable signal WEn, a read enable signal REn, and a write protection signal WPn) from the memory controller 3 via the NAND. The suffix “n” that is added to a signal name denotes that the signal is asserted at the low level. Furthermore, the logic control circuit 22 transmits a ready/busy signal R/Bn to the memory controller 3 via the NAND bus.

The signal CEn enables selection of the NAND flash memory 2. For example, a plurality of chips are selected with the signal CEn, and the NAND flash memory 2 that is included in the selected plurality of chips is selected as the selected chips. The signal CLE enables a command, which is transmitted as the signal DQ, to be latched to a command register. The signal ALE enables an address, which is transmitted as the signal DQ, to be latched to an address register. The signal WEn enables writing. The signal REn enables reading. The signal WPn protects against writing and erasing. The signal R/Bn indicates whether the NAND flash memory 2 is in a ready state (a state where a command can be received from the outside) or is in a busy state (a state where a command cannot be received from the outside). The memory controller 3 detects a state of the NAND flash memory 2 through the signal R/Bn.

The register 23 includes a command register, an address register, a status register, and the like. A command is temporarily retained in the command register. An address is temporarily retained in the address register. Data necessary for operation of the NAND flash memory 2 is temporarily retained in the status register. The register 23 is, for example, an SRAM.

The control circuit 24 receives a command from the register 23, and generally controls the NAND flash memory 2 according to a sequence that is based on this command.

The voltage generation circuit 25 receives a power source voltage from outside of the NAND flash memory 2 and generates a plurality of voltages necessary for the write operation, the read operation, and the erasing operation, from the power source voltage. The voltage generation circuit 25 supplies the generated voltage to the memory cell array 20, the row decoder 26, the sense amplifier unit 28, and the like.

The row decoder 26 receives a row address from the register 23, and decodes this row address. The row decoder 26 performs an operation of selecting a word line, based on the decoded row address. Then, the row decoder 26 transfers a plurality of voltages necessary for the write operation, the read operation, and the erasing operation to the selected block.

The column decoder 27 receives a column address from the register 23, and decodes this column address. The column decoder 27 selects any bit line based on the decoded column address.

When reading data, the sense amplifier unit 28 detects and amplifies data that is read from a memory cell transistor into a bit line. Furthermore, when writing data, the sense amplifier unit 28 transfers write data to a bit line.

When reading data, the data register 29 temporarily retains the data that is transferred from the sense amplifier unit 28, and serially transfers the retained data to the input and output circuit 21. When writing data, the data register 29 temporarily retains the data that is serially transferred from the input and output circuit 21, and transfers the retained data to the sense amplifier unit 28. The data register 29 is, e.g., an SRAM.

### 1-1-2. Plane PB

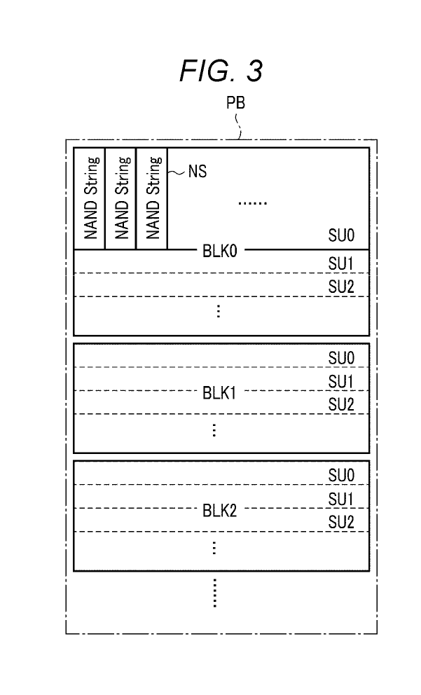

FIG. 3 is a block diagram of the plane PB that is provided in the memory cell array 20. The plane PB includes a plurality of blocks BLK (BLK 0, BLK1, BLK2, and so forth). Each of the plurality of blocks BLK includes a plurality of string units SU (SU0, SU1, SU2, and so forth). The plurality of string units SU each include a plurality of NAND strings NS. The number of blocks BLK that are provided in one plane PB, the number of string units SU that are provided in one block BLK, and the number of NAND strings NS that are provided in one string unit SU is not limited to a specific number.

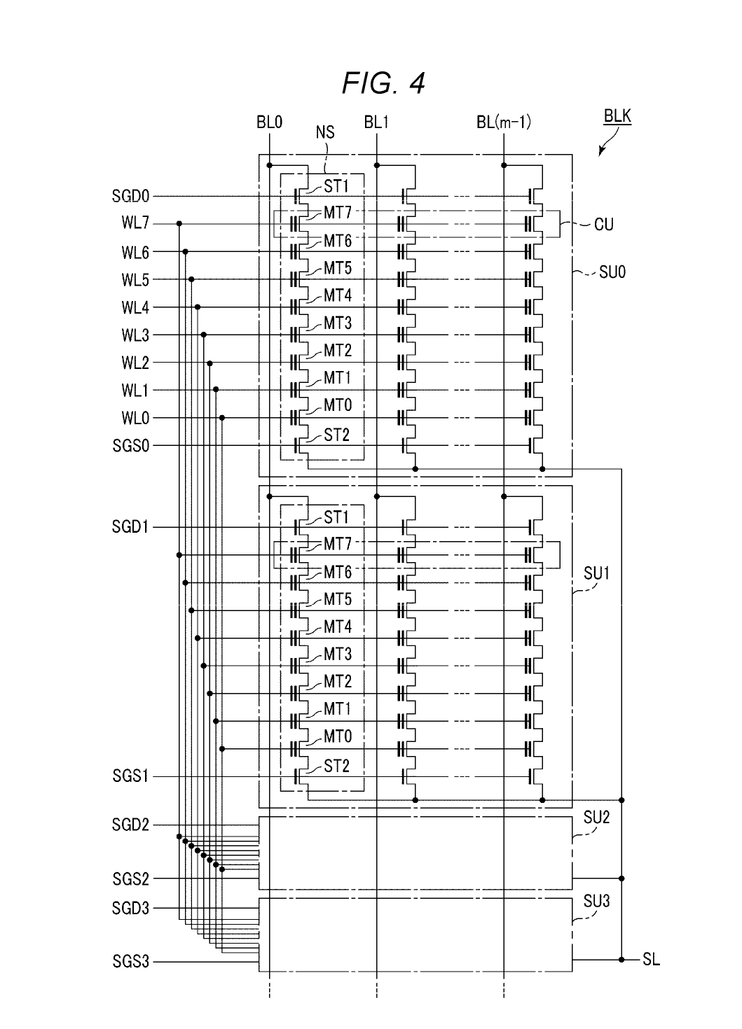

FIG. 4 is a circuit diagram of the block BLK that is provided in the plane PB. Each of the plurality of NAND strings NS includes a plurality of memory cell transistors MT, and two select transistors, select transistors ST1 and ST2. The plurality of memory cell transistors MT are connected in serial between a source of the select transistor ST1 and a drain of a select transistor ST2. In the present specification, in some cases, the memory cell transistor is referred to as a memory cell or a cell. FIG. 4 illustrates an example of a configuration in which the NAND string NS includes eight memory cell transistors MT (MT0 to MT7), but the number of memory cell transistors MT that are provided by the NAND string NS is not limited thereto. The memory cell transistor MT includes a control gate electrode and a charge storage layer. Data is stored, in a nonvolatile manner, in the memory cell transistor MT. Two- or more-bit data can be stored in the memory cell transistor MT.

Gates of a plurality of select transistors ST1 that are provided in the string unit SU0 are connected, in a shared manner, to a select gate line SGD0. In the same manner, select gate lines SGD1 to SGD3 are connected to the string units SU1 to SU3, respectively. Gates of a plurality of select transistors ST2 that are provided in the string unit SU0 are connected, in a shared manner, to a select gate line SGS0. In the same manner, select gate lines SGS1 to SGS3 are connected to the string units SU1 to SU3, respectively. The gates of the plurality of select transistors ST2 that are within each block BLK may be connected to the shared select gate line SGS. Control gates of the memory cell transistors MT0 to MT7 that are within block BLK are connected to word lines WL0 to WL7, respectively.

Within each block BLK, a drain of select transistors ST1 in the plurality of NAND strings NS that are in the same column is connected, in a shared manner, to one of the bit lines BL0 to BL (m−1). The number “m” is an integer that is equal or greater than 1. Moreover, each bit line BL connects one NAND string NS from each of the string units SU across the plurality of blocks BLK, in a shared manner. Sources of the plurality of select transistors ST2 that are provided in each block BLK are connected, in a shared manner, to a source line SL. The source line SL, for example, connects the plurality of NAND strings NS across the plurality of blocks, in a shared manner.

Pieces of data in the plurality of memory cell transistors MT that are stored within each block BLK, for example, are collectively erased. Data reading and writing are collectively performed on the plurality of memory cell transistors MT that are connected, in a shared manner, to one word line WL provided in one string unit SU. In this manner, a set of memory cell transistors MT that share a word line WL in one string unit SU is referred to as a cell unit CU. A collection one-bit data from each of the plurality of memory cell transistors MT that are in the same cell unit CU is referred to as a page. The write operation and the read operation on the cell unit CU are performed on a per-page basis.

The NAND string NS may include a dummy cell transistor. Specifically, for two dummy cell transistors, dummy cell transistors DT0 and DT1 are connected in series between the select transistor ST2 and the memory cell transistor MT0. In addition, two dummy cell transistors, dummy cell transistors DT2 and DT3 are connected in series between the memory cell transistor MT7 and the select transistor ST1. Dummy word lines DWL0 to DWL3 are connected to gates, respectively, of the dummy cell transistors DT0 to DT3. A structure of the dummy cell transistor is the same as that of the memory cell transistor. The dummy cell transistor is not designated for storing data, and has a function of reducing a disturbance that the memory cell transistor and the select transistor experience while performing the write operation or erasing operation.

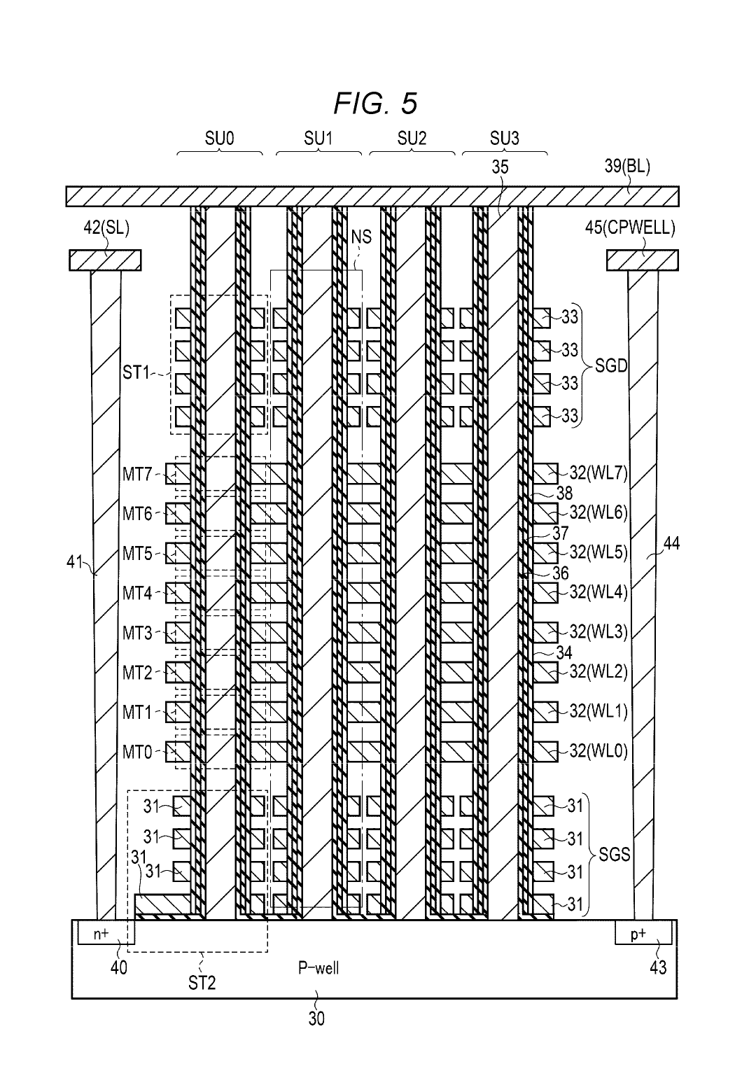

FIG. 5 is a cross-sectional diagram of one region of a block BLK. The plurality of NAND strings NS are provided on a p-type well region 30. That is, for example, a four-layered interconnection layer 31 that functions as the select gate line SGS, an eight-layered interconnection layer 32 that functions as the word lines WL0 to WL7, and for example, a four-layered interconnection layer 33 that functions as the select gate line SGD are sequentially stacked, on top of the well region 30. An insulating film that is not illustrated is provided between each of the interconnection layers that are stacked on top of each other.

The memory hole 34 passes through the interconnection layers 31, 32, and 33 and reaches the well region 30. A semiconductor layer 35 in the shape of a pillar is provided within the memory hole 34. Agate insulating film 36, a charge storage layer 37, and a block insulating film 38 are sequentially provided on a side surface of the semiconductor layer 35. The memory cell transistor MT and the select transistors ST1 and ST2 are formed at intersections of the interconnection layers and the semiconductor layer 35. The semiconductor layer 35 functions as an electric current path for the NAND string NS, and is a region in which a channel of each transistor is formed. An upper end of the semiconductor layer 35 is connected to a metal interconnection layer 39 that functions as a bit line BL.

A n+ type impurity diffusion layer 40 is provided within an upper surface region of the well region 30. A contact plug 41 is provided on the diffusion layer 40, and the contact plug 41 is connected to a metal interconnection layer 42 that functions as a source line SL. Moreover, a p+ type impurity diffusion layer 43 is provided within an upper surface region of the well region 30. A contact plug 44 is provided on the diffusion layer 43, and the contact plug 44 is connected to a metal interconnection layer 45 that functions as a well interconnection CPWELL. The well interconnection CPWELL is an interconnection through which a voltage to the semiconductor layer 35 is applied via the well region 30.

The embodiment described above are employed in the depth direction of a piece of paper which FIG. 5 is drawn, and the string unit SU has a plurality of NAND strings NS that are arranged side by side in the depth direction.

### 1-1-3. Threshold Voltage Distribution of the Memory Cell Transistor

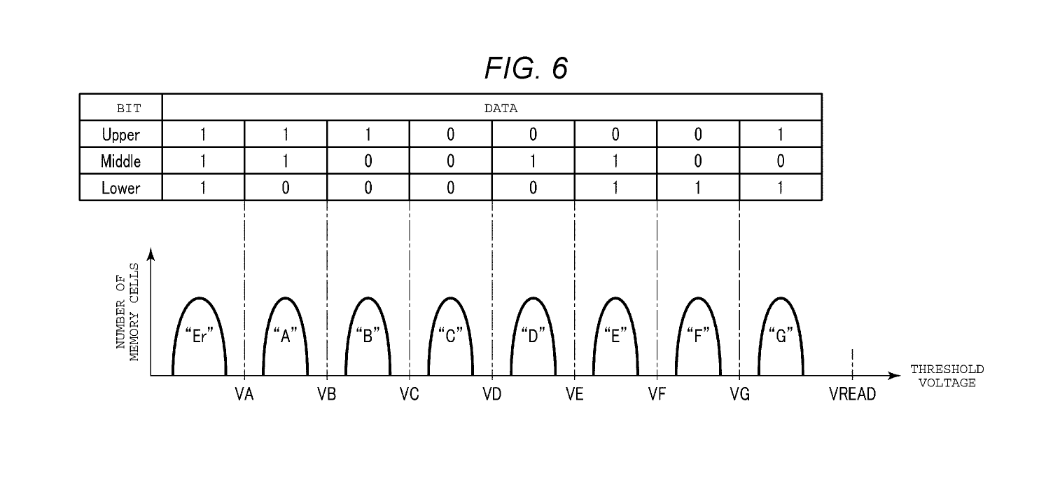

Next, a distribution of threshold voltages that can be obtained by the memory cell transistor will be described. FIG. 6 is a schematic diagram illustrating an example of the distribution of the threshold voltages of the memory cell transistor MT. Two- or more-bit data can be stored in the memory cell transistor MT. In the present embodiment, a triple level cell (TLC) scheme in a case where three-bit data is stored in the memory cell transistor MT will be described.

Three-bit data is made up of an upper bit, a middle bit, and a lower bit. In a case where three bit data is stored in the memory cell transistor MT, the memory cell transistor MT has any of eight threshold voltages. The eight threshold voltage levels are referred to as “Er”, “A”, “B”, “C”, “D”, “E”, “F”, and “G” levels, respectively, in increasing order of the threshold voltage. The plurality of memory cell transistors MT that belong to each of the “Er”, “A”, “B”, “C”, “D”, “E”, “F”, and “G” levels form a distribution.

For example, data of “111”, data of “110”, data of “100”, data of “000”, data of “010”, data of “011”, data of “001”, and data “101” are allocated to threshold voltage distributions that have the “Er”, “A”, “B”, “C”, “D”, “E”, “F”, and “G” levels, respectively. The allocation of pieces of data to the threshold voltage distributions may freely set.

For determination of data that is stored in a reading target memory cell transistor MT, a level to which the threshold voltage of the memory cell transistor MT belongs, is determined. For the level determination, read voltages VA, VB, VC, VD, VE, VF, and VG are used.

The “Er” level, for example, is equivalent to an erased state. Then, the threshold voltage of the memory cell transistor MT that is included in the “Er” level is lower than a voltage VA, and has, for example, a negative value.

The “A” level to the “G” level are equivalent to a state where charge is injected into the charge storage layer and thus data is deemed to have been written to the memory cell transistor MT, and the threshold voltage of the memory cell transistor MT that is included in each distribution has a positive value. A threshold voltage that is included in the “A” level is higher than the read voltage VA, and is equal to or lower than the read voltage VB. A threshold voltage that is included in the “B” level is higher than the read voltage VB, and is equal to or lower than the read voltage VC. A threshold voltage that is included in the “C” level is higher than the read voltage VC, and is equal to or lower than the read voltage VD. A threshold voltage that is included in the “D” level is higher than the read voltage VD, and is equal to or lower than the read voltage VE. A threshold voltage that is included in the “E” level is higher than the read voltage VE, and is equal to or lower than the read voltage VF. A threshold voltage that is included in the “F” level is higher than the read voltage VF, and is equal to or lower than the read voltage VG. A threshold voltage that is included in the “G” level is higher than the read voltage VG, and is equal to or lower than a voltage VREAD. The voltage VREAD is a voltage that is applied to a word line WL of a memory cell transistor MT of a non-reading target cell unit CU, and is higher than the threshold voltage of the memory cell transistor MT that is at any level. More precisely, regardless of data that is stored in a memory cell transistor MT, the memory cell transistor MT goes into an ON state when the voltage VREAD is applied to the gate thereof.

As described above, because each memory cell transistor MT has any of the eight distributions of the threshold voltages, eight types of states can be employed to describe the state of the memory cell transistor. Furthermore, the data writing and reading are performed on a per-page basis within one cell unit CU. In a case where three-bit data is stored in the memory cell transistor MT, the lower bit, the middle bit, and the upper bit are allocated to three pages within one cell unit CU. In the following description, the writing or the reading is collectively performed on pages to which the lower bit, the middle bit, and the upper bit are allocated respectively to a lower page, a middle page, and an upper page.

### 1-1-4. Configurations of the Sense Amplifier Unit 28 and the Data Register 29

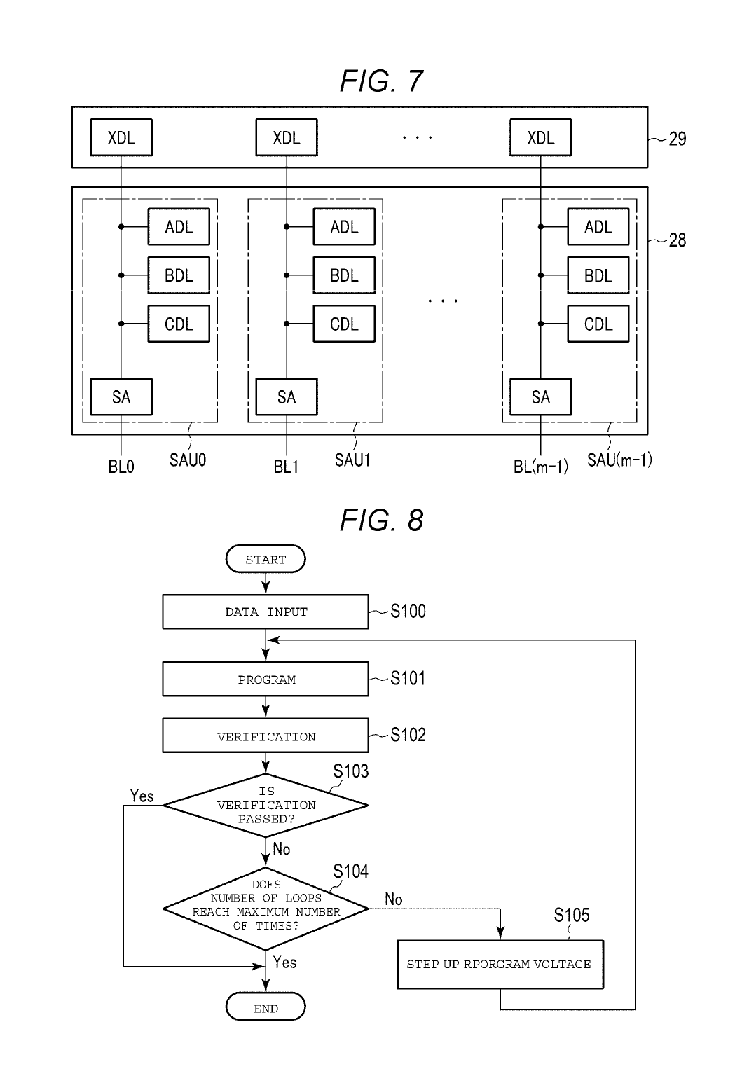

FIG. 7 is a block diagram of the sense amplifier unit 28 and the data register 29 that are illustrated in FIG. 2. FIG. 7 illustrates the sense amplifier unit 28 and the data register 29 that are associated with one plane PB. For every plane PB, the sense amplifier unit 28 and the data register 29 include a circuit that is illustrated in FIG. 7.

The sense amplifier unit 28 includes sense amplifier units SAU0 to SAU(m−1) that correspond to bit lines BL0 to BL(m−1), respectively. Each sense amplifier unit SAU includes a sense amplifier SA, and data latch circuits ADL, BDL, and CDL. The sense amplifier SA and the data latch circuits ADL, BDL, and CDL are connected to each other in such a manner that data can be transferred. The data latch circuit ADL is used for storing the lower page. The data latch circuit BDL is used for storing the middle page. The data latch circuit CLD is used for storing the upper page. The number of data latch circuits that are provided in the sense amplifier unit SAU may be changed according to the number of bits that are stored by one memory cell transistor MT.

When reading data, the sense amplifier SA detects data that is read into a corresponding bit line BL, and determines whether the data is data of “0” or data of “1”. Furthermore, when writing data, the sense amplifier SA applies a voltage to the bit line BL based on the write data.

The data register 29 includes data latch circuits XDL of which the number corresponds to the number of sense amplifier units SAU0 to SAU(m−1). The data latch circuit XDL is connected to the input and output circuit 21. The write data that is sent from the input and output circuit 21 is temporarily stored in the data latch circuit XDL. Furthermore, the read data that is sent from the sense amplifier unit SAU is temporarily stored in the data latch circuit XDL. More specifically, data transfer between the input and output circuit 21 and the sense amplifier unit 28 is performed via the data latch circuit XDL that corresponds to one page. The write data that is received by the input and output circuit 21 is transferred to the sense amplifiers SA and the data latch circuits ADL, BDL, and CDL via the data latch circuit XDL. The read data that is read by the sense amplifiers SA is transferred to the input and output circuit 21 via the data latch circuit XDL.

### 1-2. Operation

Next, operation of the memory system 1 described above will be described.

First, a general flow for the write operation will be described. FIG. 8 is a flowchart for describing the write operation.

The write operation includes a program operation and a verification operation. Then, a pair of the program operation and the verification operation, which is referred to as a software program loop is repeated, and as a result the threshold voltage of the memory cell transistor MT is changed to a target level.

First, the control circuit 24 performs a data input operation (Step S100). The data input operation is an operation in which data for the write operation is input. In the present embodiment, pieces of three-bit data are collectively written to the memory cell transistor MT. That is, with a one-time write sequence, any of the eight threshold levels is programmed into the memory cell transistor MT. In the data input operation, the lower page, the middle page, and the upper page are transferred to the data latch circuits ADL, BDL, and CDL, respectively.

Subsequently, the control circuit 24 performs the program operation (Step S101). In the program operation, a program voltage is applied to the selected word line. The program operation is an operation in which the threshold voltage of the memory cell transistor MT is increased by injecting a charge (e.g., an electron) into the charge storage layer of the memory cell transistor MT or in which the threshold voltage of the memory cell transistor MT is maintained by preventing the electron from being injected into the charge storage layer. An operation of increasing the threshold voltage is referred to as “writing of ‘0’” and an operation of maintaining the threshold voltage is referred to as “writing of ‘1’” or “write-protection”. More specifically, the writing of “0” and the writing of “1” cause the voltage of the bit line BL to be different. For example, a voltage VSS is applied to a bit line BL that corresponds to the writing of “0”. A voltage VBL (>VSS) is applied to a bit line BL that corresponds to the writing of “1”.

Subsequently, the control circuit 24 performs the verification operation (Step S102). The verification operation is an operation in which after the program operation, data in the memory cell transistor MT is read and then it is determined whether or not the threshold voltage of the memory cell transistor MT reaches a target level. In a case where the threshold voltage of the memory cell transistor MT reaches the target level, this is referred to as “the verification is passed”, and in a case where the threshold voltage of the memory cell transistor MT does not reach the target level, this is referred to as “the verification fails”.

In a case where the cell unit CU that is connected to the selected word line passes the verification (YES in Step S103), the control circuit 24 ends the write operation. As a condition for the cell unit CU to pass the verification, a case where the threshold voltages of all the memory cell transistors MT that are provided in the cell unit CU reach the target level may be available, or a case where among all of the memory cell transistors MT that are provided in the cell unit CU, the number of cells that do not pass the verification is smaller than a designated number may be available. That is, the control circuit 24 may count the number of bits (equal to the number of memory cell transistors) that fail in the verification. In case where the number of bits that fail in the verification is smaller than the designated number, the control circuit 24 may determine that the cell unit CU passes the verification.

On the other hand, in a case where there is a failure in the verification (No in Step S103), the control circuit 24 determines whether or not the number of program loops reaches a maximum number of times (Step S104). In a case where the number of program loops does not reach the maximum number of times (No in Step S104), the control circuit 24 steps up the program voltage only by predetermined step-up voltage (Step S105). Then, the control circuit 24 repeats Step S101 and subsequent steps.

On the other hand, in a case where the number of program loops reaches the maximum number of times (Yes in Step S104), the control circuit 24 ends the write operation. Then, the control circuit 24, for example, notifies the memory controller 3 that the write operation did not normally end.

### 1-2-1. Data Input Operation

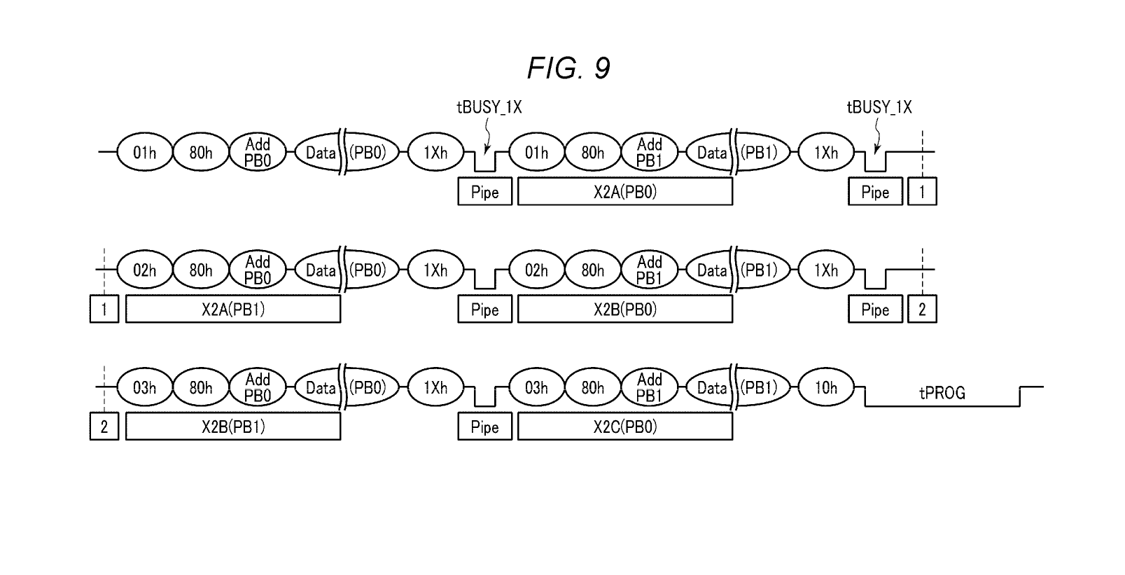

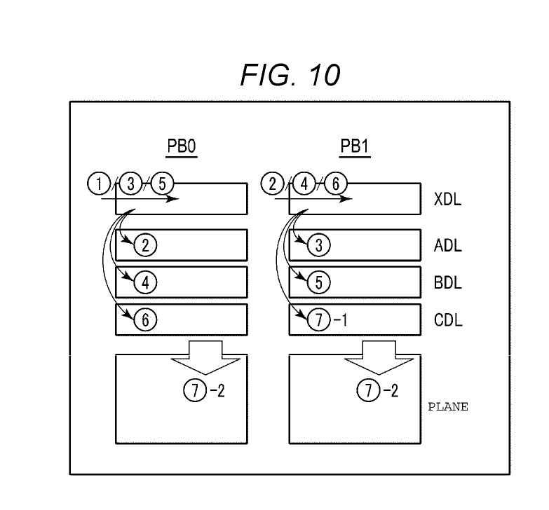

Next, the data input operation will be described in more detail. FIG. 9 is a command sequence for describing the data input operation according to the first embodiment. FIG. 9 illustrates an example in which data is written to two planes, the planes PB0 to PB1. FIG. 10 is a schematic diagram for describing a flow of data during the data input operation illustrated in FIG. 9. Each of the data latch circuits ADL, BDL, CDL, and XDL that are illustrated in FIG. 10 represents a latch circuit that corresponds to one page. A number of a step that is illustrated in FIG. 10 indicates the order of operations. Among steps “1” to “7” that are illustrated in FIG. 10, steps with the same number represent parallel operations.

The memory controller 3 issues a command “01h” and a write command “80h” to the NAND flash memory 2. The command “80h” is a command to designate an address of the NAND flash memory 2, in which data is to be input. When receiving the consecutive commands “01h” and “80h”, the NAND flash memory 2 recognizes that the following write data is lower data.

Subsequently, the memory controller 3 issues an address Add_PB0, for example, in five cycles and transmits the address Add_PB0 to the NAND flash memory 2. The address Add_PB0 is an address for designating an area that is within the plane PB0. Subsequently, the memory controller 3 transmits write data (Data (PB0)) that is lower data, to the NAND flash memory 2.

Subsequently, the memory controller 3 issues a transfer command “1Xh” to the NAND flash memory 2. The transfer command “1Xh” is a command to provide an instruction to transfer the most recently transmitted write data from the data latch circuit XDL to one of the data latch circuits ADL, BDL, and CDL.

When receiving the command “1Xh”, the NAND flash memory 2 sets a signal R/Bn to be at a level only for time tBUSY_1X, and notifies the memory controller 3 that the NAND flash memory 2 is in a “short busy” state. Being “short busy” means being busy with respect to the command “1Xh”, and short busy time tBUSY_1X is the time for issuing a trigger to start a core operation (e.g., transfer operation of ADL/BDL/CDL) of the NAND flash memory 2. Regarding the trigger time (a period of time for trigger), the control circuit 24 sets a control signal for performing the core operation, and this control signal is sent to a circuit associated with the core operation. Time tBUSY_1X is shorter than the time for transferring data, which is stored in the data latch circuit XDL, to any of the data latch circuits ADL, BDL, and CDL. That is, when the time for transferring the write data to any of the data latch circuits ADL, BDL, and CDL via the data latch circuit XDL is set to be busy time tBUSY, short busy time tBUSY_1X is shorter than busy time tBUSY.

Furthermore, in response to the data input, in the plane PB0, the NAND flash memory 2 transfers the received write data to the data latch circuit XDL that is provided in the data register 29 (Step “1” in FIG. 10). Transfer processing that transfers the last data set, in a page that are input from the outside, to the data latch circuit XDL is referred to herein as pipe processing and indicated by “Pipe” in FIG. 9. That is, the input data that is received from the memory controller 3 is sequentially transferred to the data latch circuit XDL, and at a timing for the pipe processing that is illustrated, the received pieces of write data are all present in the data latch circuit XDL. It is noted that the pipe processing may be prolonged partially up to the next command sequence as long as the pipe processing is completed until the next final address input.

Subsequently, the memory controller 3 issues the command “01h” and the write command “80h” to the NAND flash memory 2. Subsequently, the memory controller 3 issues an address Add_PB1, for example, in five cycles and transmits the address Add_PB1 to the NAND flash memory 2. The address Add_PB1 is an address for designating an area that is within the plane PB1. Subsequently, the memory controller 3 transmits write data (Data (PB1)) that is lower data, to the NAND flash memory 2.

Subsequently, the memory controller 3 issues the transfer command “1Xh” to the NAND flash memory 2. When receiving the command “1Xh”, the NAND flash memory 2 sets the signal R/Bn to be at a level only for time tBUSY_1X, and notifies the memory controller 3 that the NAND flash memory 2 is in the short busy state. Furthermore, in response to the data input, in the plane PB1, the NAND flash memory 2 transfers the received write data to the data latch circuit XDL that is provided in the data register 29 (Step “2” in FIG. 10).

Concurrently with the command sequence “01h-80h-Add(PB1)-Data-1Xh”, which is described above, the NAND flash memory 2 performs processing that transfers data of the data latch circuit XDL to the data latch circuit ADL, in the plane PB0. “X2A(PB0)” in FIG. 9 represents processing that transfers data from the data latch circuit XDL to the data latch circuit ADL, in the plane PB0. The concurrency in the processing includes partial and temporal overlapping with processing that receives at least one of the command “01h”, the write command “80h”, the address Add_PB1, and the write data. As an example, as illustrated in FIG. 9, the processing that receives one or several of the command “01h”, the write command “80h”, the address Add_PB1, and the write data and the processing for the transferring to the data latch circuit ADL are concurrently performed. Accordingly, the processing for the transferring to the data latch circuit ADL can be performed while the processing that receives the write data is performed in the background.

Subsequently, the memory controller 3 performs a command sequence “02h-80h-Add(PB0)-Data-1Xh” (a step “3” in FIG. 10). When receiving the consecutive commands “02h” and “80h”, the NAND flash memory 2 recognizes that the following write data is middle data.

Concurrently with the command sequence “02h-80h-Add(PB0)-Data-1Xh”, the NAND flash memory 2 performs the processing that transfers the data of the data latch circuit XDL to the data latch circuit ADL, in the plane PB1.

In the same manner, the memory controller 3 performs command sequences in the following order: “02h-80h-Add(PB1)-Data-1Xh” (Step “4” in FIG. 10), “03h-80h-Add(PB0)-Data-1Xh” (Step “5” in FIG. 10), “03h-80h-Add(PB1)-Data-10h” (Step “6” in FIG. 10). Concurrently with each of these command sequences, the NAND flash memory 2 performs data transfer processing “X2B(PB0)”, processing “X2B(PB1)”, and processing “X2C(PB0)”. When receiving the consecutive commands “03h” and “80h”, the NAND flash memory 2 recognizes that the following write data is upper data.

Subsequently, in response to the command “10h” that performs the writing, the NAND flash memory 2 sets the signal R/Bn to be at a level only for time tPROG, and performs the program operation. Specifically the NAND flash memory 2 performs processing “X2C(PB1) that transfers data from the data latch circuit XDL to the data latch circuit CDL, in the plane PB1 (Step “7-1” in FIG. 10). At this point in time, in each of the planes PB0 and PB1, as many pieces of data as three pages are all present in the data latch circuits ADL, BDL, and CDL. Thereafter, the NAND flash memory 2 concurrently writes data to the planes PB0 and PB1 (Step “7-2” in FIG. 10).

### 1-2-2. Status Read Operation

Next, a status read operation of checking a status of the NAND flash memory 2 will be described.

The NAND flash memory 2 can output a signal Cache-R/Bn representing a ready/busy state of the data register 29 and a signal True-R/Bn representing a ready/busy state of a core. Specifically, the signal Cache-R/Bn is in the busy state in a case where the data latch circuit XDL operates. That is, the signal Cache-R/Bn is a signal that is the same as the signal R/Bn of the NAND flash memory 2 described above. The signal True-R/Bn is in a busy state in a case where the core operates. The memory cell array 20, and the data latch circuits ADL, BDL, and CDL that within the sense amplifier unit 28 are provided in the core. When the signal R/Bn of the NAND flash memory 2 is in a ready state, the memory controller 3 possibly inputs various pieces of data (e.g., a command, an address, write data, and the like) into the NAND flash memory 2.

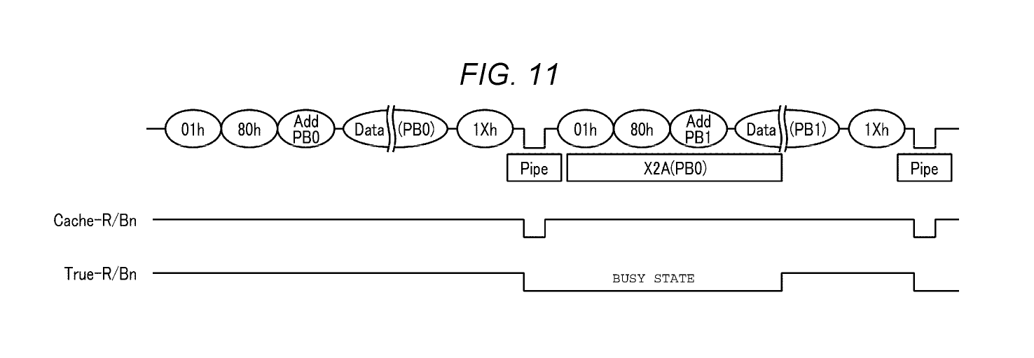

FIG. 11 illustrates states of the signal Cache-R/Bn and the signal True-R/Bn in the case of the command “1Xh”. FIG. 11 illustrates a command sequence relating to the transfer command “1Xh” that appear two times in FIG. 9.

In the case of the command “1Xh”, the NAND flash memory 2 sets the signal Cache-R/Bn to be busy only for tBUSY_1X, and then immediately return the signal Cache-R/Bn to its ready state. The signal Cache-R/Bn transitions in the same manner as the signal R/Bn. Even in a case where the data latch circuit XDL operates, the signal Cache-R/Bn is returned to its ready state. Thus, concurrently with processing that transfers the data of the data latch circuit XDL to the data latch circuit ADL/BDL/CDL, a command sequence can be received from the outside. The signal True-R/Bn is in the busy state even for a period of time for the processing “X2A” that transfers data from the data latch circuit XDL to the data latch circuit ADL.

The memory controller 3 transmits a status read command “70h” to the NAND flash memory 2, and thus checks the status of the NAND flash memory 2. That is, the memory controller 3 issues the status read command “70h” to the NAND flash memory 2. When receiving the status read command “70h”, the NAND flash memory 2 outputs status data to the memory controller 3. Accordingly, the memory controller 3 can check the status of the NAND flash memory 2. Included in the status data are the signal Cache-R/Bn and the signal True-R/Bn.

In this manner, in the present embodiment, for a period of time when the data latch circuits ADL, BDL, and CDL within the sense amplifier unit 28 operate, the signal True-R/Bn is in the busy state. Accordingly, it can be checked at any time whether or not the core operates. In the following description, the status of the signal True-R/Bn is also the same as in FIG. 11.

### 1-3. Effects of the First Embodiment

In the write operation in which the writing of pieces of two- or more-bit data is collectively performed, first processing that transfers the write data to the data latch circuit XDL, and second processing that transfers data from the data latch circuit XDL to one of the data latch circuit ADL, BDL, and CDL are performed. Then, after the first processing and the second processing are completed, a write level is fixed from pieces of data of the data latch circuits ADL, BDL, and CDL, and the programming into the memory cell transistor is performed. The first processing is performed while data input is in progress, and the second processing is performed while the busy state is entered. That is, during the second processing that transfers data from the data latch circuit XDL to one of the data latch circuit ADL, BDL, and CDL, the next command cannot be received. Moreover, the greater the number of bits that can be stored in the memory cell transistor, that is, the greater the number of pages that are retained in the sense amplifier unit, the longer the time taken for the second processing that transfers data, and the longer the wasted period of time during which the next command cannot be received.

On the other hand, according to the first embodiment, the NAND flash memory 2 receives a command sequence that includes the write command “80h” to the first plane, the address “Add”, data, and the transfer command “1Xh”, and then, is in a short busy state that is busy only for time tBUSY_1X, and while the NAND flash memory 2 is in the short busy state, the control circuit 24 sets a control signal for starting the core operation (e.g., the transfer operation of ADL/BDL/CDL) of the NAND flash memory 2. Subsequently, concurrently with processing that receives the command sequence for the second plane, the NAND flash memory 2 is set to transfer data from the data latch circuit XDL to one of the data latch circuits ADL, BDL, and CDL. That is, a second transfer processing in the first plane is set to be performed while the processing that receives the command sequence for the second plane is performed in the background.

Therefore, according to the first embodiment, in the data input operation in which the write data is set for the sense amplifier unit 28, the wasted time taken for operations other than the data input can be shortened. Furthermore, the operation other than the data input in the write operation is performed in the background, and thus program latency can be reduced. As a result, the time taken for the write operation is possibly shortened.

### 2. Second Embodiment

A second embodiment is an example in which interleaving processing is performed on four planes, planes PB0 to PB3.

### 2-1. Data Input Operation

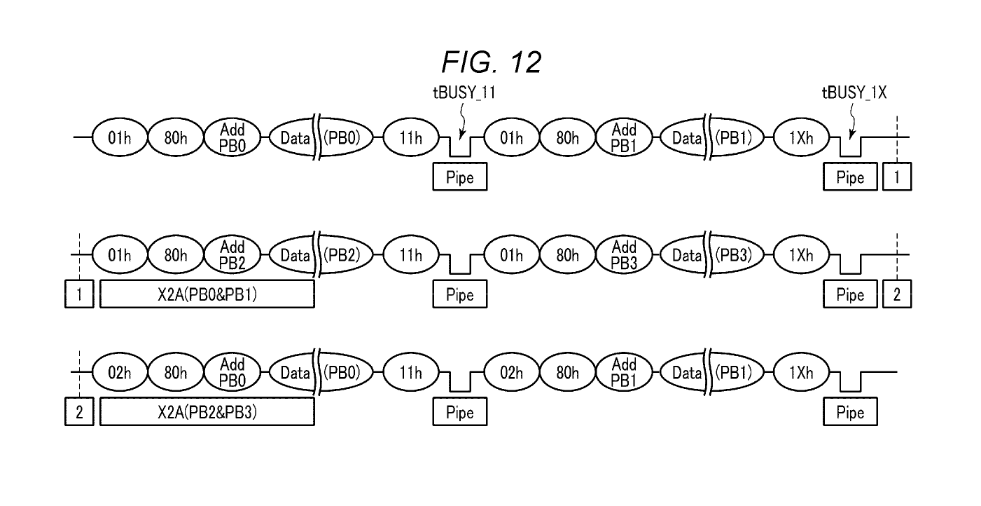

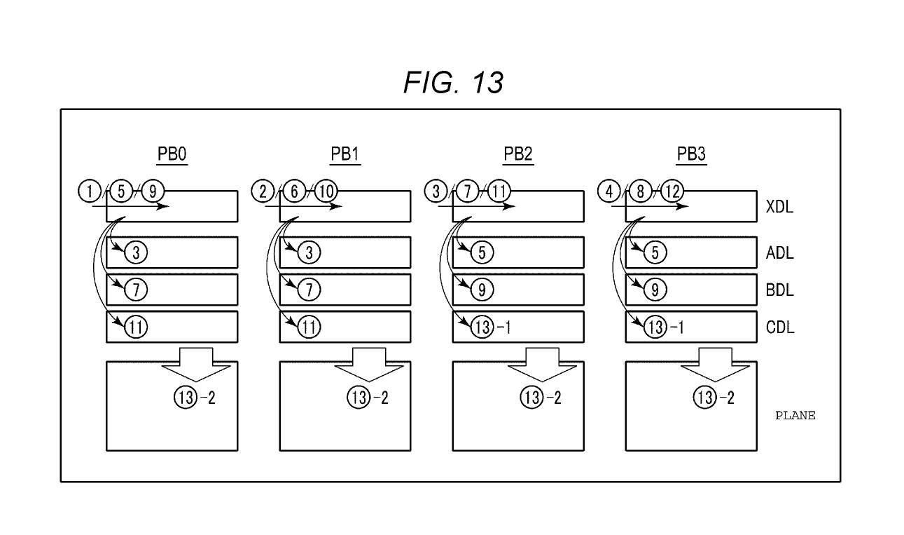

FIG. 12 is a command sequence for describing a data input operation according to a second embodiment. FIG. 13 is a schematic diagram for describing a flow of data in the data input operation that is illustrated in FIG. 12.

The memory controller 3 performs a command sequence “01h-80h-Add(PB0)-Data-11h” (Step “1” in FIG. 13). When receiving the command “11h”, for example, the NAND flash memory 2 sets the signal R/Bn to be at a level only for time tBUSY_11, and notifies the memory controller 3 that the NAND flash memory 2 is in the short busy state. It is noted that because the core operation (e.g., the transfer operation of the ADL/BDL/CDL) is not performed after receiving the command ‘11h”, a configuration may be employed in which the busy signal is not output after receiving the command “11h”. This is also true for the busy signal after the following command “11h”. In response to the data input, the NAND flash memory 2 transfers the received write data to the data latch circuit XDL, in the plane PB0.

Subsequently, the memory controller 3 performs a command sequence “01h-80h-Add(PB1)-Data-1Xh” (Step “2” in FIG. 13). When receiving the command “1Xh”, the NAND flash memory 2 sets the signal R/Bn to be at a level only for time tBUSY_1X, and notifies the memory controller 3 that the NAND flash memory 2 is in the short busy state. Furthermore, in response to the data input, the NAND flash memory 2 transfers the received write data to the data latch circuit XDL, in the plane PB1.

Subsequently, the memory controller 3 performs a command sequence “01h-80h-Add(PB2)-Data-11h” (Step “3” in FIG. 13). In response to the data input, the NAND flash memory 2 transfers the received write data to the data latch circuit XDL, in the plane PB2.

Concurrently with the command sequence “01h-80h-Add(PB2)-Data-11h”, which is described above, the NAND flash memory 2 performs the processing that transfers data of the data latch circuit XDL to the data latch circuit ADL, in each of the planes PB0 and PB1.

Subsequently, the memory controller 3 performs command sequences “01h-80h-Add(PB3)-Data-1Xh” and “02h-80h-Add(PB0)-Data-11h” (Steps “4” and “5” in FIG. 13). Concurrently with the command sequence “02h-80h-Add(PB0)-Data-11h”, the NAND flash memory 2 performs the processing that transfers the data of the data latch circuit XDL to the data latch circuit ADL, in each of the planes PB2 and PB3.

Subsequently, the memory controller 3 performs a command sequence “02h-80h-Add(PB1)-Data-1Xh” (Step “6” in FIG. 13). Although an illustration in FIG. 12 is omitted, in the same manner, the memory controller 3 performs command sequences “02h-80h-Add(PB2)-Data-11h (Step “7” in FIG. 13), “02h-80h-Add(PB3)-Data-1Xh (Step “8” in FIG. 13), “03h-80h-Add(PB0)-Data-11h (Step “9” in FIG. 13), “03h-80h-Add(PB1)-Data-1Xh (Step “10” in FIG. 13), “03h-80h-Add(PB2)-Data-11h (Step “11” in FIG. 13), and “03h-80h-Add(PB3)-Data-10h (Step “12” in FIG. 13). Furthermore, in Steps “7”, “9”, and “11”, processing for transfer from the data latch circuit XDL to the data latch circuit BDL (or CDL) is performed concurrently with the command sequence.

Thereafter, in response to the command “10h”, the NAND flash memory 2 sets the signal R/Bn to be at a level only for time tPROG, and performs the program operation. Specifically, the NAND flash memory 2 performs processing that transfers data from the data latch circuit XDL to the data latch circuit CDL, in the planes PB2 and PB3 (Step “13-1” in FIG. 13). At this point in time, in each of the planes PB0 to PB3, as many pieces of data as three pages are all present in the data latch circuits ADL, BDL, and CDL. Thereafter, the NAND flash memory 2 concurrently writes data to the planes PB0 to PB3 (Step “13-2” in FIG. 13).

### 2-2. Modification Example

Next, a data input operation according to a modification example will be described. In the modification example, processing for transferring to the data latch circuit in one plane is performed using the transfer command “1Xh”.

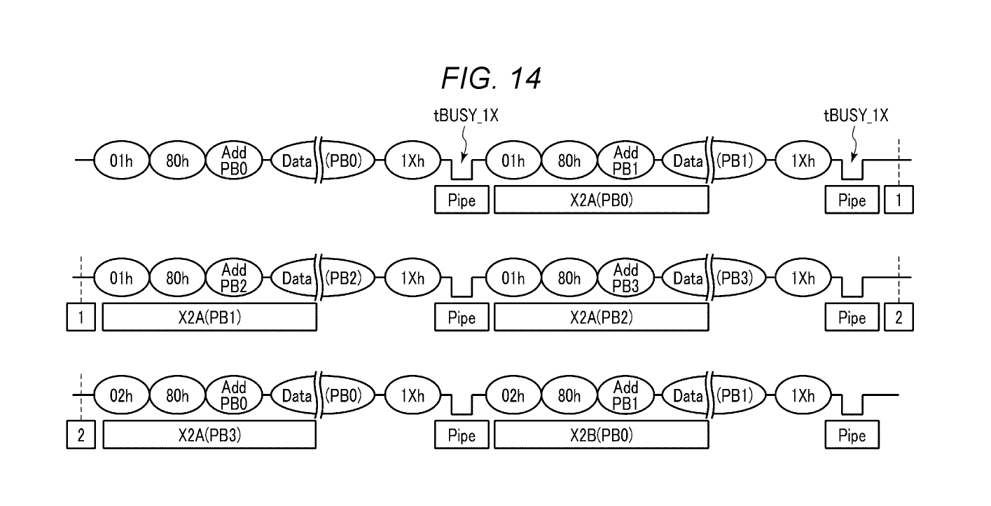

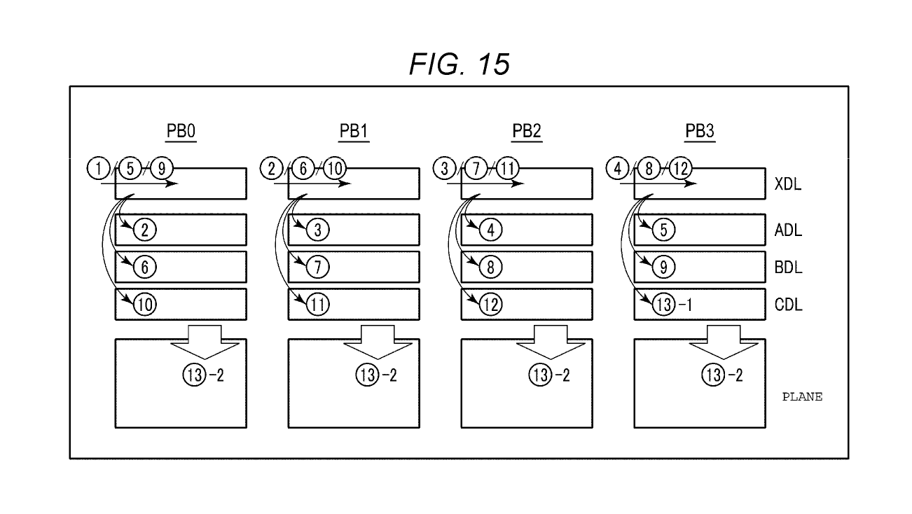

FIG. 14 is a command sequence for describing the data input operation according to the modification example. FIG. 15 is a schematic diagram for describing a flow of data in the data input operation that is illustrated in FIG. 14. It is noted that command sequences up to and including Step “6” in FIG. 15 are illustrated in FIG. 14.

The memory controller 3 performs command sequences “01h-80h-Add(PB0)-Data-1Xh” (Step “1” in FIG. 15), “01h-80h-Add(PB1)-Data-1Xh” (Step “2” in FIG. 15), “01h-80h-Add(PB2)-Data-1Xh” (Step “3” in FIG. 15), “01h-80h-Add(PB3)-Data-1Xh” (Step “4” in FIG. 15), “02h-80h-Add(PB0)-Data-1Xh” (Step “5” in FIG. 15), “02h-80h-Add(PB1)-Data-1Xh” (Step “6” in FIG. 15), “02h-80h-Add(PB2)-Data-1Xh” (Step “7” in FIG. 15), “02h-80h-Add(PB3)-Data-1Xh” (Step “8” in FIG. 15), “03h-80h-Add(PB0)-Data-1Xh” (Step “9” in FIG. 15), “03h-80h-Add(PB1)-Data-1Xh” (Step “10” in FIG. 15), “03h-80h-Add(PB2)-Data-1Xh” (Step “11” in FIG. 15), and “03h-80h-Add(PB3)-Data-1Xh” (Step “12” in FIG. 15).

Then, in response to the transfer command “1Xh”, the NAND flash memory 2 performs processing for transfer from the data latch circuit XDL to any of the data latch circuits ADL, BDL, and CDL, concurrently with the command sequence.

### 2-3. Effects of the Second Embodiment

As described above, according to the second embodiment, the interleaving operation can be performed on the plane PB0 to PB3. Furthermore, concurrently with the processing that receives the command sequence, the processing that transfers data from the data latch circuit XDL to any of the data latch circuits ADL, BDL, and CDL can be performed. Furthermore, it is also possible that the interleaving operation is performed on many more planes.

### 3. Third Embodiment

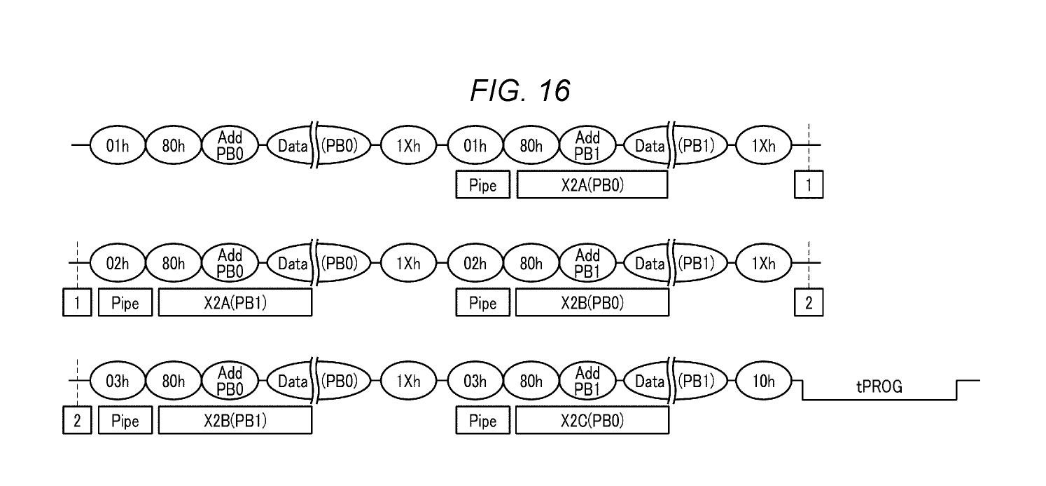

In a third embodiment, without the short busy state between command sequences, the NAND flash memory 2 performs an operation of transferring input data to the data latch circuit XDL and the core operation (e.g., the transfer operation of the ADL/BDL/CDL) without being short busy, while the processing that receives the command sequence is performed in the background. FIG. 16 is a command sequence for describing a data input operation according to the third embodiment.

The memory controller 3 performs the command sequence “01h-80h-Add(PB0)-Data-1Xh”. In response to the data input, the NAND flash memory 2 transfers the received write data to the data latch circuit XDL, in the plane PB0.

Subsequently, the memory controller 3 performs the command sequence ‘01h-80h-Add(PB1)-Data-1Xh”. Concurrently with the command sequence “01h-80h-Add(PB1)-Data-1Xh”, the NAND flash memory 2 sets the control signal for starting the core operation (e.g., the transfer operation of the ADL/BDL/CDL) and performs the processing that transfers the data of the data latch circuit XDL to the data latch circuit ADL, without being short busy, in the plane PB0. Furthermore, in response to the data input, the NAND flash memory 2 transfers the received write data to the data latch circuit XDL, in the plane PB1.

In the same manner, the memory controller 3 performs command sequences “02h-80h-Add(PB0)-Data-1Xh”, “02h-80h-Add(PB1)-Data-1Xh”, “03h-80h-Add(PB0)-Data-1Xh”, and “03h-80h-Add(PB1)-Data-10h”.

Concurrently with the command sequences described above, the NAND flash memory 2 sets the control signal for starting the core operation (e.g., the transfer operation of the ADL/BDL/CDL) and performs the processing for the transfer from the data latch circuit XDL to the data latch circuit ADL, BDL, or CDL), without being short busy.

Therefore, according to the third embodiment, without being short busy, the NAND flash memory 2 can perform the processing that transfers the write data to the data latch circuit XDL and the processing that transfers data from the data latch circuit XDL to the data latch circuit ADL, BDL, or CDL, while the processing that receives the command sequence is performed in the background.

Furthermore, the NAND flash memory 2 does not output the busy signal between the command sequences. Accordingly, the time taken for the data input operation can be much more shortened. It is noted that it is also possible that the third embodiment is applied to the second embodiment.

### 4. Other Modification Examples

In the embodiments described above, as an example, the case where three-bit data is stored in one memory cell transistor is described, but cases are not limited thereto and two-bit data may be storable in one memory cell transistor (a multilevel cell (MLC)), and four- or more-bit data may be storable in one memory cell transistor. In such embodiments, the various operations described above in the embodiments can also be implemented.

In the embodiments described above, as an example, the case where a MONOS film is used for the memory cell is described, but cases are not limited thereto and a floating gate memory cell may be used.

A configuration of the memory cell array disclosed in the following U.S. applications may be used in the embodiments: U.S. patent application Ser. No. 14/407,403 filed on Mar. 19, 2009, which is entitled “THREE-DIMENSIONAL STACKED NON-VOLATILE SEMICONDUCTOR MEMORY,” U.S. patent application Ser. No. 12/406,524 filed on Mar. 18, 2009, which is entitled “THREE DIMENSIONAL STACKED NONVOLATILE SEMICONDUCTOR MEMORY,” U.S. patent application Ser. No. 12/679,991 filed on Mar. 25, 2010, which is entitled “NON-VOLATILE SEMICONDUCTOR STORAGE DEVICE AND METHOD OF MANUFACTURING THE SAME,” and U.S. patent application Ser. No. 12/532,030 filed on Mar. 23, 2009, which is entitled “SEMICONDUCTOR MEMORY AND METHOD FOR MANUFACTURING SAME.” All of these patents are incorporated by reference herein in their entireties.

A unit of data erasing that is performed can be a block BLK or be smaller than the block BLK. An erase method disclosed in the following U.S. applications may be used in the embodiments: U.S. patent application Ser. No. 13/235,389, filed on Sep. 18, 2011, which is entitled “NONVOLATILE SEMICONDUCTOR MEMORY DEVICE,” U.S. patent application Ser. No. 12/694,690 filed on Jan. 27, 2010, which is entitled “NON-VOLATILE SEMICONDUCTOR STORAGE DEVICE,” and U.S. patent application Ser. No. 13/483,610 filed May 30, 2012, which is entitled “NONVOLATILE SEMICONDUCTOR MEMORY DEVICE AND DATA ERASE METHOD THEREOF.” All of these patents are incorporated by reference herein in their entireties.

In the present specification, the term “connection” means that an electrical connection is made, and for example, does not exclude the presence of a separate element between two elements that are connected to each other.

The following modification examples (1) to (4) can be applied to the embodiments described above.

(1) In the read operation, a voltage that is applied a word line which is selected in the read operation at an “A” level, for example, falls within a range from 0 V to 0.55 V. The voltage is not limited to this, and may fall within any of the ranges, from 0.1 V to 0.24 V, from 0.21 V to 0.31 V, from 0.31 V to 0.4 V, from 0.4 V to 0.5 V, and from 0.5 V to 0.55 V.

“A voltage that is applied to a word line which is selected in the read operation at a “B” level, for example, falls within a range of 1.5 V to 2.3 V. The voltage is not limited to this, and may fall within any of the ranges, from 1.65 V to 1.8 V, from 1.8 V to 1.95 V, from 1.95 V to 2.1 V, and from 2.1 V to 2.3 V.

“A voltage that is applied to a word line which is selected in the read operation at a “C” level, for example, falls within a range of 3.0 V to 4.0 V. The voltage is not limited to this, and may fall within any of the ranges, from 3.0 V to 3.2 V, from 3.2 V to 3.4 V, from 3.4 V to 3.5 V, from 3.5 V to 3.6 V, and from 3.6 V to 4.0 V. The time (tRead) for the read operation, for example, may fall within ranges from 25 μs to 38 μs, from 38 μs to 70 μs, and from 70 μs to 80 μs.

(2) The write operation includes the program operation and the verification operation, which are described above. A voltage that is first applied to a word line that is selected at the time of the program operation, for example, falls within a range from 13.7 V to 14.3 V. The voltage is not limited to this, and may fall within any of the ranges, from 13.7 V to 14.0 V and from 14.0 V to 14.6 V. A voltage that is applied to a non-selected word line at the time of the program operation, for example, may fall within a range from 6.0 V to 7.3 V. The voltage is not limited to this case. For example, the voltage may fall within a range from 7.3 V to 8.4 V and may be 6.0 V or below.

In the write operation, a voltage that, when selecting an odd-numbered word line, is first applied to the selected word line, and a voltage that, when selecting an even-numbered word line, is first applied to the selected word line may be different from each other. In the write operation, a pass voltage to be applied may be changed depending on whether the non-selected word line is an odd-numbered word line or an even-numbered word line.

In a case where the program operation is set to be in accordance with an incremental step pulse program (ISPP), as a step-up width of the program voltage, for example, approximately 0.5 V is given. The time (tProg) for the write operation, for example, may fall within ranges, from 1700 μs to 1800 μs, from 1800 μs to 1900 μs, and from 1900 μs to 2000 μs.

(3) In the erasing operation, a voltage that is first applied to a well which is formed on an upper portion of semiconductor substrate and above which the memory cells described above are arranged, for example, falls with a range from 12.0 V to 13.6V. The voltage is not limited to this case, and for example, may fall within ranges from 13.6 V to 14.8 V, from 14.8 V to 19.0 V, from 19.0 V to 19.8 V, and from 19.8 V to 21.0 V.

The time (tErase) for the erasing operation, for example, may fall within ranges, from 3000 μs to 4000 μs, from 4000 μs to 5000 μs, and from 4000 μs to 9000 μs.

(4) A structure of the memory cell has a charge storage layer that is provided, via a tunnel insulating film with a thickness of 4 to 10 nm, on a semiconductor substrate (silicon substrate). The charge storage layer can be set to have a structure in which an insulating film of SiN, SiON, or the like, which is 2 nm to 3 nm in thickness, and a film of polysilicon that is 3 nm to 8 nm in thickness are stacked on top of each other. Furthermore, a metal such as Ru may be added to the polysilicon. The charge storage layer has an insulating film thereon. The insulating film, for example, has a silicon oxide film with a thickness of 4 nm to 10 nm, which is interposed between a lower layer High-k film with a thickness of 3 nm to 10 nm and an upper layer High-k film with a thickness of 3 nm to 10 nm. As the High-k film, HfO or the like is used. Furthermore, the thickness of the silicon oxide film can be greater than the thickness of the High-k film. A control electrode with a thickness of 30 nm to 70 nm is formed, via a material with a thickness of 3 nm to 10 nm, on the insulating film. A material here is a film of metal oxide such as TaO or a film of metal nitride such as TaN. W or the like can be used for the control electrode. Furthermore, an air gap can be formed between each of the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
first and second planes of memory cells;
first and second latch circuits for the first plane of memory cells, wherein data stored in the first latch circuit is transferred to the first plane of memory cells via the second latch circuit;
third and fourth latch circuits for the second plane of memory cells, wherein data stored in the third latch circuit is transferred to the second plane of memory cells via the fourth latch circuit; and
a control circuit configured to perform a sequence of operations in response to commands, the sequence of operations including a first operation to transfer first data associated with the commands from the first latch circuit to the second latch circuit and, concurrently with the first operation, a second operation to transfer second data associated with the commands into the third latch circuit.

2. The semiconductor memory device according to claim 1, wherein the sequence of operations includes a third operation to transfer third data associated with the commands into the first latch circuit and, concurrently with the third operation, a fourth operation to transfer the second data associated with the commands from the third latch circuit to the fourth latch circuit.

3. The semiconductor memory device according to claim 2, wherein the first data and the second data correspond to lower bit data and middle bit data to be stored respectively in a group of memory cells in the first plane.

4. The semiconductor memory device according to claim 1, further comprising:
a logic control circuit configured to generate a first ready/busy signal and a second ready/busy signal, in response to a status read command.

5. The semiconductor memory device according to claim 4, wherein the first ready/busy signal is at a ready level and the second ready/busy signal is at a busy level at a start of the first operation.

6. The semiconductor memory device according to claim 1, wherein the second operation includes receipt of a sequence of commands and the second data followed by a transfer of the received second data into the third latch circuit, and the first operation is performed during the receipt of the sequence of commands and the second data and prior to the transfer of the received second data into the third latch circuit.

7. The semiconductor memory device according to claim 1, wherein the second operation includes receipt of a sequence of commands and the second data followed by a transfer of the received second data into the third latch circuit, and a transfer of the first data into the first latch and the first operation are performed during the receipt of the sequence of commands and the second data and prior to the transfer of the received second data into the third latch circuit.

8. A semiconductor memory device comprising:
first, second, third, and fourth planes of memory cells;
first and second latch circuits for the first plane of memory cells, wherein data stored in the first latch circuit is transferred to the first plane of memory cells via the second latch circuit;
third and fourth latch circuits for the second plane of memory cells, wherein data stored in the third latch circuit is transferred to the second plane of memory cells via the fourth latch circuit;
fifth and sixth latch circuits for the third plane of memory cells, wherein data stored in the fifth latch circuit is transferred to the third plane of memory cells via the sixth latch circuit;
seventh and eighth latch circuits for the fourth plane of memory cells, wherein data stored in the seventh latch circuit is transferred to the fourth plane of memory cells via the eighth latch circuit; and
a control circuit configured to perform a sequence of operations in response to commands, the sequence of operations including a first operation to transfer first data associated with the commands from the first latch circuit to the second latch circuit, a second operation to transfer second data associated with the commands from the third latch circuit to the fourth latch circuit, and a third operation to transfer third data associated with the commands into the fifth latch circuit, wherein
the first and second operations are carried out concurrently and while the third operation is being carried out.

9. The semiconductor memory device according to claim 8, wherein the third operation includes receipt of a sequence of commands and the third data followed by a transfer of the received third data into the fifth latch circuit, and the first and second operations are performed during the receipt of the sequence of commands and the third data and prior to the transfer of the received third data into the fifth latch circuit.

10. The semiconductor memory device according to claim 8, wherein the sequence of operations includes a fourth operation to transfer fourth data associated with the commands into the first latch circuit, a fifth operation to transfer the third data associated with the commands from the fifth latch circuit to the sixth latch circuit, and a sixth operation to transfer fifth data associated with the commands from the seventh latch circuit to the eighth latch circuit, wherein
the fifth and sixth operations are carried out concurrently and while the fourth operation is being carried out.

11. The semiconductor memory device according to claim 10, wherein the fourth operation includes receipt of a sequence of commands and the fourth data followed by a transfer of the received fourth data into the first latch circuit, and the fifth and sixth operations are performed during the receipt of the sequence of commands and the fourth data and prior to the transfer of the received fourth data into the first latch circuit.

12. The semiconductor memory device according to claim 10, wherein the first data and the fourth data correspond to lower bit data and middle bit data to be stored respectively in a group of memory cells in the first plane.

13. The semiconductor memory device according to claim 8, wherein the second operation includes receipt of a sequence of commands and the second data followed by a transfer of the received second data into the third latch circuit, and a transfer of the first data into the first latch and the first operation are performed during the receipt of the sequence of commands and the second data.

14. A semiconductor memory device comprising:
first, second, third, and fourth planes of memory cells;
first and second latch circuits for the first plane of memory cells, wherein data stored in the first latch circuit is transferred to the first plane of memory cells via the second latch circuit;
third and fourth latch circuits for the second plane of memory cells, wherein data stored in the third latch circuit is transferred to the second plane of memory cells via the fourth latch circuit;
fifth and sixth latch circuits for the third plane of memory cells, wherein data stored in the fifth latch circuit is transferred to the third plane of memory cells via the sixth latch circuit;
seventh and eighth latch circuits for the fourth plane of memory cells, wherein data stored in the seventh latch circuit is transferred to the fourth plane of memory cells via the eighth latch circuit; and
a control circuit configured to perform a sequence of operations in response to commands, the sequence of operations including a first operation to transfer first data associated with the commands from the first latch circuit to the second latch circuit, a second operation to transfer second data associated with the commands into the third latch circuit, a third operation to transfer the second data associated with the commands from the third latch circuit to the fourth latch circuit, and a fourth operation to transfer third data associated with the commands into the fifth latch circuit, wherein
the first and second operations are carried out concurrently and thereafter the third and fourth operations are carried out concurrently.

15. The semiconductor memory device according to claim 14, wherein
the second operation includes receipt of a sequence of commands and the second data followed by a transfer of the received second data into the third latch circuit, and the first operation is performed during the receipt of the sequence of commands and the second data and prior to the transfer of the received second data into the third latch circuit, and
the fourth operation includes receipt of a sequence of commands and the third data followed by a transfer of the received third data into the fifth latch circuit, and the third operation is performed during the receipt of the sequence of commands and the third data and prior to the transfer of the received third data into the fifth latch circuit.

16. The semiconductor memory device according to claim 14, wherein
the second operation includes receipt of a sequence of commands and the second data followed by a transfer of the received second data into the third latch circuit, and a transfer of the first data into the first latch and the first operation are performed during the receipt of the sequence of commands and the second data and prior to the transfer of the received second data into the third latch circuit, and
the fourth operation includes receipt of a sequence of commands and the third data followed by a transfer of the received third data into the fifth latch circuit, and a transfer of the second data into the third latch and the third operation are performed during the receipt of the sequence of commands and the third data and prior to the transfer of the received third data into the fifth latch circuit.

17. The semiconductor memory device according to claim 14, wherein the sequence of operations includes a fifth operation to transfer the third data associated with the commands from the fifth latch circuit to the sixth latch circuit, and a sixth operation to transfer fourth data associated with the commands into the seventh latch circuit, wherein
the fifth operation is carried out while the sixth operation is being carried out.

18. The semiconductor memory device according to claim 14, wherein the sequence of operations includes a seventh operation to transfer the fourth data associated with the commands from the seventh latch circuit to the eighth latch circuit, and an eighth operation to transfer fifth data associated with the commands into the first latch circuit, wherein
the seventh operation is carried out while the eighth operation is being carried out.

19. The semiconductor memory device according to claim 18, wherein the first data and the fifth data correspond to lower bit data and middle bit data to be stored respectively in a group of memory cells in the first plane.
